(19) United States
(12) Patent Application Publication
(10) Pub. No.: US 2018/0042131 A1
(43) Pub. Date: Feb. 8, 2018

(54) GLASS HOUSING AND ELECTRONIC DEVICE HAVING THE SAME

(71) Applicants: SHENZHEN O-FILM TECH. CO., LTD., Shenzhen (CN); NANCHANG O-FILM OPTICAL TECHNOLOGY CO., LTD., Nanchang (CN)

(72) Inventors: Wei LIU, Nanchang (CN); Genchu TANG, Nanchang (CN); Bin TANG, Nanchang (CN)

(73) Assignees: SHENZHEN O-FILM TECH. CO., LTD., Shenzhen (CN); NANCHANG O-FILM OPTICAL TECHNOLOGY CO., LTD., Nanchang (CN)

(21) Appl. No.: 15/452,729

(22) Filed: Mar. 8, 2017

(30) Foreign Application Priority Data
Aug. 3, 2016 (CN) 201610629013.4

(51) Int. Cl. H05K 5/03; H05K 5/02; B32B 1/02; B32B 17/06; C03C 17/00; C03C 21/00

(52) U.S. Cl. CPC H05K 5/03; C03C 17/00; C03C 21/002; B32B 1/02; B32B 17/06; H05K 5/0243; C03C 2217/72; C03C 2218/119; B32B 2457/00; H04B 1/3888

(57) ABSTRACT

A glass housing includes an inner surface, an outer surface spaced from the inner surface, and a side peripheral surface connecting the outer surface and the inner surface, wherein a distance between the inner surface and the outer surface ranges from 0.2 mm to 1.0 mm, the inner surface and the outer surface have central axes, the inner surface is curved to one side with the central axis of the inner surface as a center to form an arcuate inner curved surface, the outer surface is curved to the same side with the central axis of the outer surface as a center to form an arcuate outer curved surface, the inner curved surface and the outer curved surface have radii of 50 mm to 1000 mm, the glass housing has a height of 0.5 mm to 5 mm.

### RELATED APPLICATIONS

This application claims priority under 35 U.S.C. §119 to Chinese Patent Application No. 201610629013.4, filed on Aug. 3, 2016. The entire content of which is incorporated herein in its entirety.

### FIELD OF THE INVENTION

The present disclosure relates to electronic components, and more particularly relates to a glass housing and an electronic device having the glass housing.

### BACKGROUND OF THE INVENTION

With the popularity of electronic devices such as smart phones and watches which are provided with a touch screen, various manufacturers compete to release differentiated products to attract consumers. A highlight design emerging in current market is to design a housing of the electronic device to be a curved surface. The electronic device with the curved surface can better fit the hand of the user, thus improving the comfort of holding and handling. If the housing of the watch is designed to be a curved surface, it can also better fit the wrist of the user, thus improving the comfort of wearing. In addition, a displaying housing with the curved surface can make the displaying content have more stereoscopic effect, the appearance can thereby be improved. The electronic device becomes more popular using glass as a material of the housing due to its better texture. However, the glass housing of the electronic device, especially with the curved surface, is susceptible to cracking due to accidental fall.

### SUMMARY

Therefore, it is necessary to provide a glass housing capable of dispersing stress and enhancing strength, and an electronic device having the glass housing.

A glass housing includes an inner surface; an outer surface opposite to the inner surface; and a circumferential surface interconnecting the outer surface and the inner surface, wherein a distance between the inner surface and the outer surface ranges from 0.2 mm to 1.0 mm, the inner surface and the outer surface have central axes, the inner surface is bent to one side with respect to the central axis of the inner surface as a center to form an arcuate inner curved surface, the outer surface is bent to the same side with respect to the central axis of the outer surface as a center to form an arcuate outer curved surface, the inner curved surface and the outer curved surface have radii of curvature of 50 mm to 1000 mm, the glass housing has a height of 0.5 mm to 5 mm.

An electronic device is provided including the aforementioned glass housing.

By the configuration of the structural parameters, the aforementioned glass housing can disperse the concentrated stress, enhance the integral strength and reduce the risk that cracks emerge easily by a slight collision due to the concentrated stress.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a front view of a glass housing according to an embodiment;

FIG. 2 is a cross-sectional view taken along line A-A of FIG. 1;

FIG. 3 is a cross-sectional view taken along line B-B of FIG. 1; and

FIG. 4 is a perspective view of an electronic device according to an embodiment.

### DETAILED DESCRIPTION OF THE EMBODIMENTS

Embodiments of the invention are described more fully hereinafter with reference to the accompanying drawings, in which preferred embodiments of the invention are shown. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art.

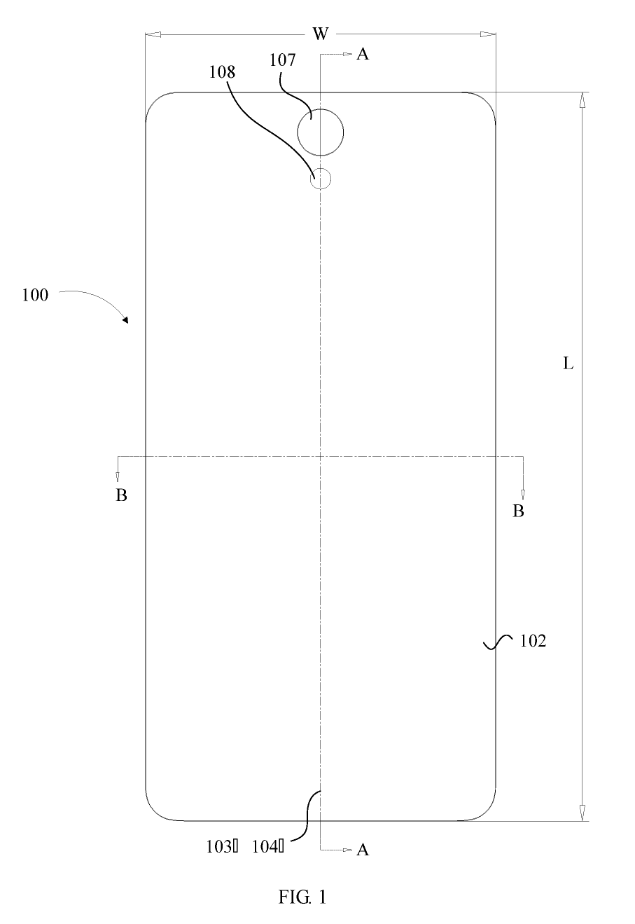

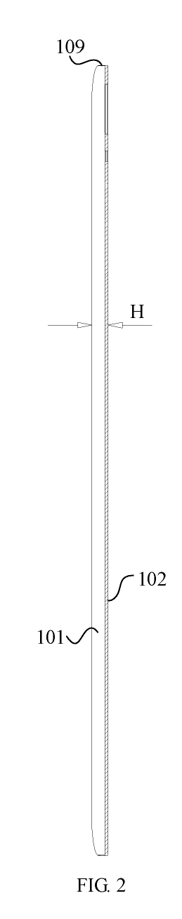

As shown in FIG. 1 to FIG. 3, a glass housing 100 according to an embodiment can be applied to electronic devices such as smart phones or the like, and it can serve as a displaying housing and a back cover plate of phones or the like.

The glass housing 100 includes an inner surface 101, an outer surface 102 opposite to the inner surface 101, and a circumferential surface 109 interconnecting the outer surface 102 and the inner surface 101.

A distance between the inner surface 101 and the outer surface 102 ranges from 0.2 mm to 1.0 mm, i.e. the glass housing 100 has a thickness of 0.2 mm to 1.0 mm.

The inner surface 101 has a central axis 103, and the inner surface 101 is symmetrical about the central axis 103. The outer surface 102 also has a central axis 104, and the outer surface 102 is symmetrical about the central axis 104.

The inner surface 101 is bent to one side with respect to the central axis 103 as a center to form an arcuate inner curved surface, the outer surface 102 is bent to the same side with respect to the central axis 104 as a center to form an arcuate outer curved surface. The inner curved surface and the outer curved surface have radii R of curvature of 50 mm to 1000 mm.

In some embodiments, radii R of curvature of the inner curved surface and the outer curved surface are the same, i.e., the glass housing 100 has a uniform thickness, such that the stress concentration can be eliminated and the integral strength of the glass housing 100 can be enhanced.

The glass housing 100 has a height H of 0.5 mm to 5 mm. The height H refers to a distance between a plane where two parallel edge lines 105, 106 of the inner surface 101 is located and the central axis 104 of the outer surface 102.

By the configuration of the aforementioned structural parameters, the concentrated stress applied to the glass housing 100 is dispersed, thus an integral strength of the glass housing 100 is enhanced. The risk that cracks emerge easily by a slight collision due to the concentrated stress is reduced.

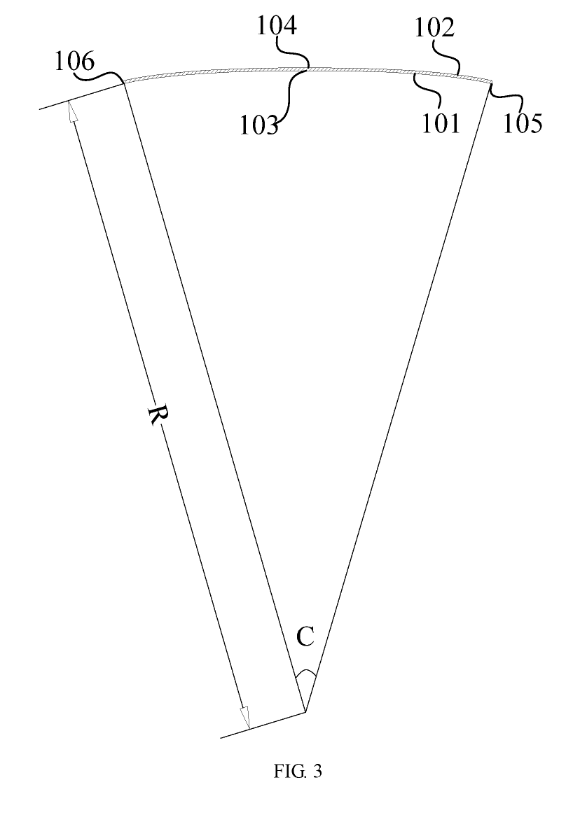

In the cross-section of the glass housing 100 shown in FIG. 3, an angle C formed by two connection lines between each end of the inner surface 101 and a center of an arc located by the inner surface 101, i.e. a central angle C subtended by the arc ranges from 60° to 180°. A central angle C subtended by an arc located by the outer surface 102 also ranges from 60° to 180°.

In some embodiments, as shown in FIG. 1, an orthographic proj ection of the glass housing 100 is shaped as a rectangular with rounded corners. The rectangular orthographic projection has a length L of 50 mm to 500 mm, and a width W of 30 mm to 300 mm.

In some embodiments, the glass housing 100 further defines a first mounting hole 107 and a second mounting hole 108 penetrating the inner surface 101 and the outer surface 102. Orthographic projections of centers of the first mounting hole 107 and the second mounting hole 108 fall on the central axis 103, 104. The first and the second mounting holes 107, 108 are circular, and a diameter of the first mounting hole 107 is greater than a diameter of the second mounting hole 108. In the particular application, the first mounting hole 107 can serve as a viewfinder hole for a camera, the second mounting hole 108 can be used to accommodate an infrared sensor.

In some embodiments, at least one of the inner surface 101 and the outer surface 102 is provided with a decorative layer. The decorative layer can color the glass housing 100 to provide a more appealing appearance. The decorative layer can be formed on the inner surface 101 and/or the outer surface 102 by ink printing or adhering. When the decorative layer is formed by ink printing, the decorative layer has a thickness of 5 μm to 40 μm. When the decorative layer is formed by adhering a decorative film, the decorative film has a thickness of 10 μm to 125 μm. The decorative film can be formed by screen printing an explosion-proof membrane with a substrate, and it can also be formed by directly screen printing an adhesive without a substrate.

During a manufacturing process of the glass housing 100, at least one of the inner surface 101 and the outer surface 102 can be subjected to a strengthening treatment, such that the inner surface 101 and/or the outer surface 102 is provided with a surface compressive stress layer. In general, during the machining process of the glass, edges of the glass surface will inevitably generate micro-cracks, which can seriously reduce the strength of the glass. Although a size of the micro-crack can be decreased by physical machining processes such as polishing, further chemical strengthening treatment can achieve a better effect. For example, under a certain temperature, the glass can be immersed into a molten salt, the alkali metal ions in the glass and the alkali metal ions in the molten salt are interchanged by diffusion, thereby the surface compressive stress layer having a certain thickness is formed on the glass surface. The surface compressive stress layer is not an additional layered structure adhering to the glass surface, but is a strengthening layer formed inwardly from the glass surface with a certain thickness. The surface compressive stress layer makes the micro-crack not easy to be extended, thereby enhancing the strength of the glass.

In some embodiments, by the first strengthening treatment, the obtained surface compressive stress layer has a thickness of 50 μm to 100 μm. The surface compressive stress layer has a compressive stress of 200 MPa to 300 MPa. A central tensional stress between the inner surface 101 and the outer surface 102 is less than or equal to 100 MPa.

In some embodiments, by the second strengthening treatment, the obtained surface compressive stress layer has a thickness of 60 μm to 69 μm, i.e. a depth of the ion exchange in the second strengthening treatment process is less than that in the first strengthening treatment process. The surface compressive stress layer has a compressive stress of 710 MPa to 850 MPa. A central tensional stress between the inner surface 101 and the outer surface 102 is less than or equal to 160 MPa. By multiple strengthening treatment, the surface compressive stress can be improved, and the strength of the glass housing 100 is thereby improved. However, the central tensional stress is increased accompanying with an improvement of the surface compressive stress. The excessive central tensional stress will crack the glass from the inside out, thus the central tensional stress should be controlled, i.e. the surface compressive stress cannot be increased indefinitely.

In some embodiments, at least one of the inner surface 101 and the outer surface 102 is further attached with an anti-reflection layer. The anti-reflection layer can be formed by evaporation, sputtering or the like.

In some embodiments, the outer surface 102 is further attached with an anti-fingerprint layer. An initial water droplet angle of the anti-finger printer layer is greater than or equal to 110°. The so-called water droplet angle is an angle formed by the intersection of solid-liquid interface and gas-liquid interface, which is located at the solid-liquid-gas three phases interfaces. The greater the water droplet angle, the better the hydrophobicity and anti-fouling performance of the anti-fingerprint layer. The initial water droplet angle is the water droplet angle measured in the absence of the use and destruction of the formed anti-fingerprint layer. As the time of formation of the anti-fingerprint layer is prolonged and the wearing degree is increased, the water droplet will decrease.

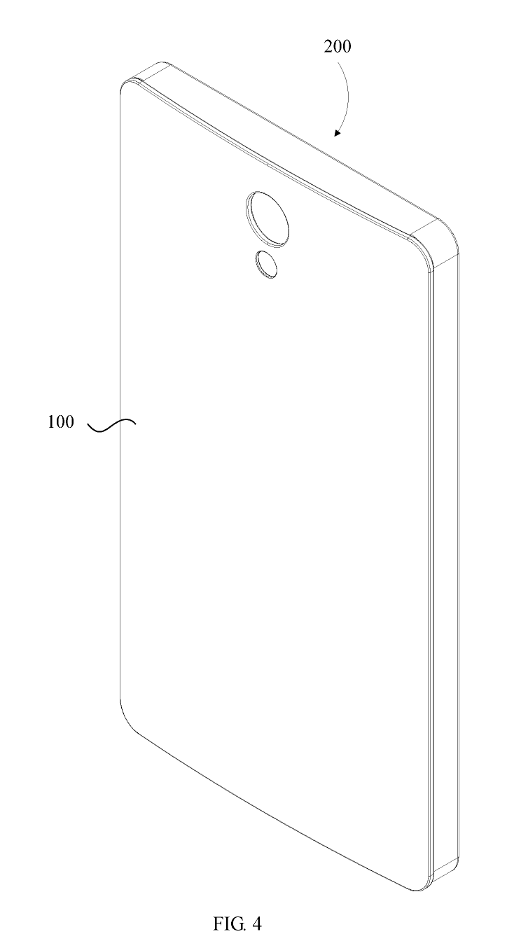

As shown in FIG. 4, an electronic device 200 according to an embodiment includes the aforementioned glass housing 100. The electronic device 200 is a smart phone. In some embodiments, the electronic device 200 can also be a tablet computer or the like.

Although the respective embodiments have been described one by one, it shall be appreciated that the respective embodiments will not be isolated. Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

The foregoing descriptions are merely specific embodiments of the present invention, but are not intended to limit the protection scope of the present invention. Any variation or replacement readily figured out by a person skilled in the art within the technical scope disclosed in the present invention shall all fall within the protection scope of the present invention. Therefore, the protection scope of the present invention shall be subject to the protection scope of the appended claims.

What is claimed is:

1. A glass housing, comprising:
an inner surface;
an outer surface opposite to the inner surface; and
a circumferential surface interconnecting the outer surface and the inner surface;
wherein a distance between the inner surface and the outer surface ranges from 0.2 mm to 1.0 mm, the inner surface and the outer surface have central axes, the inner surface is bent to one side with respect to the central axis of the inner surface as a center to form an arcuate inner curved surface, the outer surface is bent to the same side with respect to the central axis of the outer surface as a center to form an arcuate outer curved surface, the inner curved surface and the outer curved surface have radii of curvature of 50 mm to 1000 mm, the glass housing has a height of 0.5 mm to 5 mm.

2. The glass housing of claim 1, wherein radii of curvature of the inner curved surface and the outer curved surface are the same.

3. The glass housing of claim 2, wherein central angles C corresponding to arcs of the inner curved surface and the outer curved surface range from 60° to 180°.

4. The glass housing of claim 1, wherein an orthographic projection of the glass housing has a rectangular shape, the orthographic projection has a length of 50 mm to 500 mm, the orthographic projection has a width of 30 mm to 300 mm.

5. The glass housing of claim 1, further defining a first mounting hole and a second mounting hole penetrating the inner surface and the outer surface, orthographic projections of centers of the first mounting hole and the second mounting hole fall on the central axis of the inner surface or the outer surface.

6. The glass housing of claim 1, wherein the inner surface is provided with a decorative layer formed by ink printing, the decorative layer has a thickness of 5 μm to 40 μm.

7. The glass housing of claim 1, wherein the inner surface is provided with a decorative layer formed by adhering a decorative film, the decorative film has a thickness of 10 μm to 125 μm.

8. The glass housing of claim 1, wherein at least one of the inner surface and the outer surface is provided with a surface compressive stress layer, the surface compressive stress layer has a thickness of 50 μm to 100 μm, the surface compressive stress layer has a compressive stress of 200 MPa to 300 MPa, a central tensional stress between the inner surface and the outer surface is less than or equal to 100 MPa.

9. The glass housing of claim 1, wherein at least one of the inner surface and the outer surface is provided with a surface compressive stress layer, the surface compressive stress layer has a thickness of 60 μm to 69 μm, the surface compressive stress layer has a compressive stress of 710 MPa to 850 MPa, a central tensional stress between the inner surface and the outer surface is less than or equal to 160 MPa.

10. The glass housing of claim 1, wherein at least one of the inner surface and the outer surface is attached with an anti-reflection layer.

11. The glass housing of claim 1, wherein the outer surface is attached with an anti-fingerprint layer, and an initial water droplet angle of the anti-fingerprinter layer is greater than or equal to 110°.

12. An electronic device, comprising a glass housing, wherein the glass housing comprises:
an inner surface;
an outer surface opposite to the inner surface; and
a circumferential surface interconnecting the outer surface and the inner surface;
wherein a distance between the inner surface and the outer surface ranges from 0.2 mm to 1.0 mm, the inner surface and the outer surface have central axes, the inner surface is bent to one side with respect to the central axis of the inner surface as a center to form an arcuate inner curved surface, the outer surface is bent to the same side with respect to the central axis of the outer surface as a center to form an arcuate outer curved surface, the inner curved surface and the outer curved surface have radii of curvature of 50 mm to 1000 mm, the glass housing has a height of 0.5 mm to 5 mm.
